(19) United States
(12) Patent Application Publication
(10) Pub. No.: US 2023/0217627 A1
(43) Pub. Date: Jul. 6, 2023

(54) COOLING CASE PROVIDING COOLING OF ELECTRONIC CARDS

(71) Applicant: ASELSAN ELEKTRONIK SANAYI VE TICARET ANONIM SIRKETI, Ankara (TR)

(72) Inventors: Murat PARLAK, Ankara (TR); Vedat Yagci, Ankara (TR); Ahmet Sahin SEN, Ankara (TR)

(73) Assignee: ASELSAN ELEKTRONIK SANAYI VE TICARET ANONIM SIRKETI, Ankara (TR)

(21) Appl. No.: 18/088,644

(22) Filed: Dec. 26, 2022

(30) Foreign Application Priority Data
Dec. 30, 2021 (TR) 2021/021953

(51) Int. Cl. H05K 7/20; H05K 7/14

(52) U.S. Cl. CPC H05K 7/20254; H05K 7/1424; H05K 7/20263; H05K 7/20436

(57) ABSTRACT

A cooling case provides cooling of electronic cards. The cooling case provides efficient cooling of electronic cards found in military electronics packaging, and includes a cold plate having a fin structure.

### CROSS REFERENCE TO THE RELATED APPLICATIONS

This application is based upon and claims priority to Turkish Patent Application No. 2021/021953, filed on Dec. 30, 2021, the entire contents of which are incorporated herein by reference.

### TECHNICAL FIELD

The invention relates to the cooling of electronic cards, namely it provides a cooling case to cool electronic cards in military electronics packaging efficiently.

### BACKGROUND

Today in military electronics packaging printed circuit boards need to be fixed to a mechanics for cooling as well as meeting mechanical and electrical requirements. They shall be resistant against shock and vibration mechanically and required connectors shall be combine with one another electrically. Particularly, cooling of boards having very high heating by heat transmission method provides huge advantages in many platforms. The case where the boards are located can be more than one. However, if one or more than one of the boards have excessive heat load, all cooling architecture in the case may change.

In the current related art, the electronic board (PCB) is used together with a wedge mechanism and this structure, which is connected to each other outside, is mounted by sliding it into the case from the upper part. Because of space and interface resistance inside the wedge lock mechanisms used, higher thermal resistance occurs. In the related art, the biggest problem is that the thermal resistances are about 0.2° C./W in the filled mechanical place, and this resistance is 0.5° C./W in the wedge-lock surface. In this case heat is not equally distributed and parallel conveyed heat compound resistance varies between 0.143-0.2° C./W. In such case, when a heat load of 70 W is transferred from only one wall via wedge mechanism, at least temperature increase of minimum 10° C. occurs there from.

Upon investigation of the prior art, a document numbered US2012175094 is seen. This document relates to cooling systems adapted for use in cooling heat sources such as integrated circuit components, processors and memory modules in computer systems and particularly a cold plate embodied to provide efficient heat exchange. The structure disclosed under the document describes a conventional liquid cooling module. The liquid in this structure cools the heat source by entering finned structure inlet interface and exiting from another outlet interface.

In conclusion, developments have been made in embodiments used in cooling electronic boards and, therefore, new design/concept eliminating the above disadvantages and offering solutions to existing systems are needed.

### SUMMARY

The present invention relates to cooling case meeting the needs mentioned above, eliminating all disadvantages and providing some additional advantages.

The main purpose of the invention is to provide cooling of electronic boards used in military vehicles. For this purpose, a method to improve to provide other requirements when compared to any method of cooling with heat transmission known before. By this method a method to minimize thermal performance loss caused by wedge mechanism of a board having very high heat load is developed. With this method a slot is provided on board area of the case and the plate called cold plate and used to take heat from electronic member to case wall is put into case from outside. Wedge mechanism is fully removed. Edges of elongated plate are kept wide, and fins are added to increase cooling effectiveness and flange gaskets are added thereon to provide sealing and thus both fluid cooling case and air-cooling cases are provided with high, effectiveness, easy production and considerably advantage embodiment.

In order to achieve all of the advantages mentioned above and described in detail below, the present invention relates to cooling case providing cooling of electronic cards in military electronics packaging and located on electronic cards and characterized by;
cold plate opening provided on cooling case to provide installment of cold plate to cooling case side part,
fins providing transmission of heat of electronic cards located onto cold plate to fluid passing through cooling case, located in parts where cold plate is connected to cooling case,
outer cover closed onto cold plate opening to cut connection of cold plate with outer environment.

The structural and characteristic features and all advantages of the invention will be understood better in the figures given below and the detailed description by reference to the figures. Therefore, the assessment should be made based on the figures and taking into account the detailed descriptions.

### BRIEF DESCRIPTION OF THE DRAWINGS

In order to make the embodiment and additional members being subject of the present invention as well as the advantages clearer for better understanding, it should be assessed with reference to the fallowing described figures.

FIG. 1 is a demounted view of cooling case of the invention.

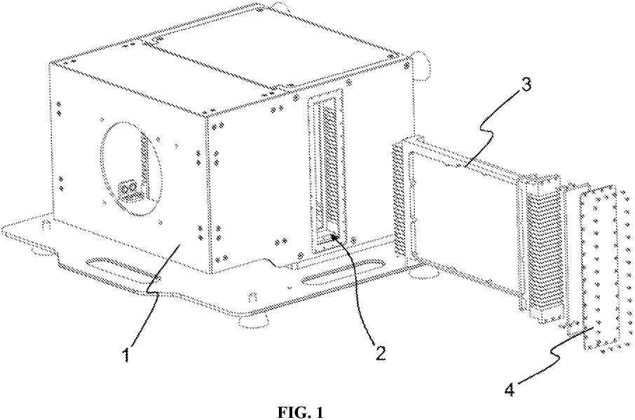

FIG. 2 is a detailed view of cold plate of the invention.

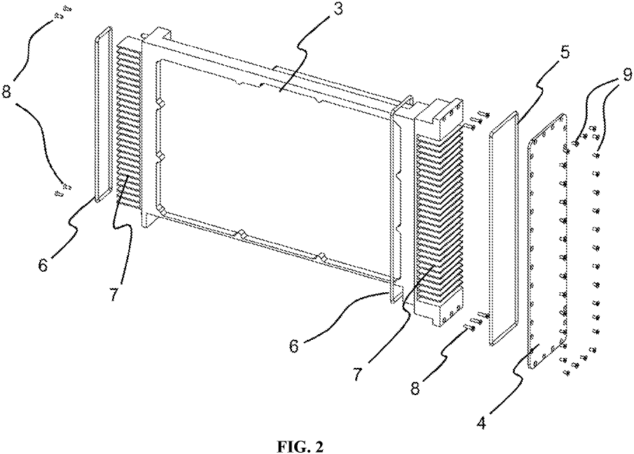

FIG. 3 is a mounted view of cooling case of the invention.

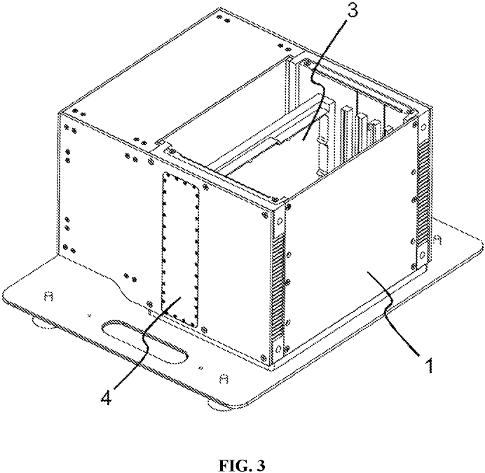

### REFERENCE NUMBERS

1. Cooling case
2. Cold plate opening
3. Cold plate
4. Outer cover
5. Primary sealing member
6. Secondary sealing member
7. Fins
8. Primary connection member
9. Secondary connection member

### DETAILED DESCRIPTION OF THE EMBODIMENTS

In this detailed description, the preferred embodiments of the cooling case (1) being subject of this invention have been disclosed solely for the purpose of better understanding of the subject and described in a manner not causing any restrictive effect.

The invention is a cooling case (1) providing cooling case including a cold plate (3) of electronic cards in military electronics packaging and located on electronic cards and comprises
cold plate opening (2) provided on cooling case (1) to provide installment of cold plate (3) to cooling case (1) side part,
fins (7) providing transmission of heat of electronic cards located onto cold plate (3) to fluid passing through cooling case (1), located in parts where cold plate (3) is connected to cooling case (1),
outer cover (4) closed onto cold plate opening (2) to cut connection of cold plate (3) with outer environment.

Cooling case (1) of the invention includes in the most general form, a cold plate (3) where electronic card is located. Cold plate (3) is mounted to cooling case (1) by passing it through cold plate opening (2) located on one side of cooling case (1). Connection of cold plate (3) to cooling case (1) is provided by primary connection members (8) which are preferably screw. An outer cover (4) is connected onto cold plate opening (2) to cut connection of cold plate (3) mounted into cooling case (1) with outer environment. Also connection of outer cover (4) to cooling case (1) is provided by secondary connection members (9) which are preferably screw.

Fins (7) are provided on side parts where cold plate (3) is connected to cooling case (1). Similarly, inner walls where cooling case (1) is connected to cold plate (3) are of finned form. Said fins (7) provide transmission of heat taken by cold plate (3) to fluid passing through cooling case (1). The areas where fins (7) are connected on cooling case (1) have areas containing air or fluid passing formed on cooling case (1). Thus fins (7) are enabled to take heat directly (without use of any connection part) from cold plate (3).

Secondary sealing members (6) are provided between cold plate (3) and cooling case (1) in order to provide sealing between cold plate (3) and cooling case (1). Also, primary sealing member (5) is provided between outer cover (4) and cooling case (1). Said primary sealing member (5) and secondary sealing members (6) are preferably gasket. Thus, a sealing structure is achieved in cases (1) run by both air cooling and fluid cooling and thermal loss is prevented.

With embodiment of invention cold plate (3) is on fins (7) and thus contact with direct fluid (air or fluid) is provided and a performance loss of 10 - 15° C. that might occur in a card having 100 W-120W heat load to occur in the related art is eliminated. Also, if it is desired to use said card at higher performance, fin (7) design of cold plate (3) is changed and thermal performance can be improved without need to change cooling case (1).

What is claimed is:

1. A cooling case, comprising:
a cold plate located on electronic cards in military electronics packaging, wherein the cooling case cools the electronic cards,
a cold plate opening formed on the cooling case, wherein the cold plate opening provides an installment of the cold plate to a side part of the cooling case,
fins, wherein the fins provide transmission of heat of the electronic cards located on the cold plate to a fluid passing through the cooling case, wherein the fins are at a location where the cold plate is connected to the cooling case, and
an outer cover closed onto the cold plate opening, wherein the outer cover cuts a connection of the cold plate with an outer environment.

2. The cooling case according to claim 1, wherein the cold plate comprises a fin wall, wherein the fin wall fits the fins at a location where the cooling case is connected to cold plate.

3. The cooling case according to claim 1, further comprising an area where the fins are connected to the cooling case, wherein the area has air or a fluid formed on the cooling case passing through.

4. The cooling case according to claim 1, further comprising a secondary sealing member located between the cooling case and the cold plate, wherein the secondary sealing member provides sealing.

5. The cooling case according to claim 1, further comprising a primary sealing member, wherein the primary sealing member is located between the cooling case and the outer cover, wherein the primary sealing member provides sealing.

6. The cooling case according to claim 2, further comprising an area where the fins are connected to the cooling case, wherein the area has air or a fluid formed on the cooling case passing through.
